(19) United States
(12) Patent Application Publication
(10) Pub. No.: US 2024/0255548 A1
(43) Pub. Date: Aug. 1, 2024

(54) MEASUREMENT SYSTEM, DEVICE FOR DERIVING CONVERSION FACT OR, DEVICE FOR MEASURING VOLTAGE

(71) Applicant: Nippon Telegraph and Telephone Corporation, Tokyo (JP)

(72) Inventors: Naruto ARAI, Musashino-shi, Tokyo (JP); Masato MARUYAMA, Musashino-shi, Tokyo (JP); Jun KATO, Musashino-shi, Tokyo (JP)

(21) Appl. No.: 18/559,866

(22) PCT Filed: May 12, 2021
(86) PCT No.: PCT/JP2021/018037

§ 371 Date: Nov. 9, 2023

(51) Int. Cl. G01R 15/16; G01R 19/00

(52) U.S. Cl. CPC G01R 15/16; G01R 19/0053

(57) ABSTRACT

A wearable measurement system includes a voltage measurement apparatus and a conversion coefficient acquisition apparatus, and measures a ground voltage of electromagnetic noise generated in a cable. The voltage measurement apparatus includes a lower electrode, an upper electrode arranged opposite to the lower electrode, and a voltage measurement circuit connected between the lower electrode and the upper electrode. The conversion coefficient acquisition apparatus includes a first lower electrode, a second lower electrode arranged side by side at the same height as the first lower electrode, an upper electrode arranged opposite to the lower electrodes, a voltage measurement circuit connected between the lower electrode and the upper electrode, and an oscillation circuit connected to the lower electrode and the upper electrode and outputting a signal of a predetermined frequency. The lower electrodes of the voltage measurement apparatus and the conversion coefficient acquisition apparatus have a container shape.

### TECHNICAL FIELD

The present invention relates to a measurement system, a conversion coefficient acquisition apparatus, and a voltage measurement apparatus.

### BACKGROUND ART

Asymmetric Digital Subscriber Line (ADSL) communications are techniques for providing broadband services using frequency bands from 25.875 kHz to 1.104 MHZ. ADSL communications have been widely used because of the advantages of using existing metal telephone lines for broadband services.

It is known that a communication failure occurs due to electromagnetic noise of the same band as that of a signal used for ADSL communication. When it is suspected that the communication failure is caused by electromagnetic noise, the frequency and intensity of electromagnetic noise on a power cable connected to a communication cable and a communication apparatus are measured in order to search the source of electromagnetic noise and to select an appropriate noise filter. Since the electromagnetic noise often forms a loop having the ground or a metallic floor material connected to the ground as a return path, the ground voltage of the electromagnetic noise is often measured. Hereinafter, the ground and the metallic floor material connected to the ground are generally referred to as the ground.

The ground voltage of the electromagnetic noise is measured by grounding a measuring instrument such as an oscilloscope and bringing a passive probe connected to the oscilloscope into contact with a cable to be measured. Alternatively, the measurement is performed by clamping the cable over the coating with a capacitive voltage probe connected to the oscilloscope.

In an environment where grounding is difficult, the voltage is measured without grounding, and the measurement result is corrected by using the ground capacitance of the ground of the measuring instrument.

### CITATION LIST

### Non Patent Literature

[NPL 1] N. Arai, K. Okamoto, and J. Kato, “Wearable Measurement Method for Voltage to Ground of Conducted Noise on Unshielded Cables,” 2020 International Symposium on Electromagnetic Compatibility (EMC EUROPE), 2020.

### SUMMARY OF INVENTION

### Technical Problem

The inventors have proposed a wearable measuring instrument of NPL 1 as a measuring instrument which does not require grounding. An operator can measure the ground voltage of electromagnetic noise flowing in a cable by wearing a shoe-like wearable measuring instrument and contacting the cable to be measured. The shoe-like wearable measuring instrument has different roles on the left and right sides. A device mounted on one foot is a voltage measurement device for measuring a voltage generated inside the device due to electromagnetic noise. A device mounted on the other foot is a conversion coefficient acquisition device for acquiring a conversion coefficient for obtaining a ground voltage of the electromagnetic noise from the voltage measured by the voltage measurement device. The conversion coefficient has frequency characteristics.

In the voltage measurement device of NPL 1, an upper electrode and a lower electrode are arranged so as to face each other, and a voltage generated in a resistor connected between the upper electrode and the lower electrode due to electromagnetic noise is measured. In NPL 1, it is assumed that the upper electrode forms capacitance only between the sole and the lower electrode of the operator. However, in practice, electrostatic capacitance is also formed between the upper electrode and the ground serving as the reference potential. When the capacitance becomes large, the voltage measured by the voltage measurement device becomes small. That is, there is a problem that it is difficult to measure small electromagnetic noise and to measure the electromagnetic noise when the distance between the measurement environment and the ground is distant from each other.

In the conversion coefficient acquisition device of NPL 1, an upper electrode and two lower electrodes are arranged so as to face each other. An oscillation circuit is connected between the upper electrode and one of the lower electrodes. When the oscillation circuit outputs a signal, a voltage generated in a resistor connected between the upper electrode and the other lower electrode is measured to acquire a conversion coefficient for obtaining a ground voltage from the voltage measured by the voltage measurement device. It is apparent that the conversion coefficient acquisition device has a structure in which a capacitance is formed between the upper electrode and the ground, and connection between the upper electrode and the ground is assumed in NPL 1. When the capacitance becomes large, the voltage observed in the conversion coefficient acquisition device becomes small when a signal is output from the oscillation circuit. In other words, there is a problem that the measurement becomes difficult when the distance between the measurement environment and the ground is separated.

In view of the aforementioned circumstances, an object of the present invention is to improve the measurement capability of an electromagnetic noise measuring instrument.

### Solution to Problem

A measurement system according to one aspect of the present invention is a measurement system for measuring a ground voltage of electromagnetic noise generated in a cable, the measurement system comprising a conversion coefficient acquisition apparatus and a voltage measurement apparatus, wherein the conversion coefficient acquisition apparatus includes a first lower electrode, a second lower electrode arranged side by side at the same height as the first lower electrode, a first upper electrode arranged opposite to the first lower electrode and the second lower electrode, a first voltage measurement circuit connected between the first lower electrode and the first upper electrode, and an oscillation circuit that is connected to the second lower electrode and the first upper electrode and outputs a signal of a predetermined frequency, the first voltage measurement circuit measuring a first voltage generated in the first voltage measurement circuit when the oscillation circuit outputs a signal while an operator stands on the first upper electrode and is not in contact with the cable, and obtaining a conversion coefficient based on the first voltage, and the voltage measurement apparatus includes a third lower electrode, a second upper electrode arranged opposite to the third lower electrode, and a second voltage measurement circuit connected between the third lower electrode and the second upper electrode, the second voltage measurement circuit measuring a second voltage generated in the second voltage measurement circuit while the operator stands on the second upper electrode and is in contact with the cable, and obtaining a ground voltage of the electromagnetic noise generated in the cable by multiplying the second voltage by the conversion coefficient, and at least one of the first lower electrode, the second lower electrode, or the third lower electrode being in a container shape with a bottom surface and side walls around the bottom surface.

### Advantageous Effects of Invention

According to the present invention, the measurement capability of an electromagnetic noise measuring instrument can be improved.

### BRIEF DESCRIPTION OF DRAWINGS

FIG. 1 is a diagram showing an example of a measurement image obtained by a wearable measurement system according to a present embodiment.

FIG. 2 is a schematic diagram showing an example of a configuration of a voltage measurement apparatus.

FIG. 3 is a cross-sectional view for explaining the positional relationship between an upper electrode and a lower electrode of the voltage measurement apparatus.

FIG. 4 is a cross-sectional view for explaining another positional relationship between the upper electrode and the lower electrode of the voltage measurement apparatus.

FIG. 5 is a schematic diagram showing an example of a configuration of a conversion coefficient acquisition apparatus.

FIG. 6 is a cross-sectional view for explaining the positional relationship between an upper electrode and a lower electrode of the conversion coefficient acquisition apparatus.

FIG. 7 is a cross-sectional view for explaining another positional relationship between the upper electrode and the lower electrode of the conversion coefficient acquisition apparatus.

FIG. 8 is a side view for explaining another positional relationship between the upper electrode and the lower electrode of the conversion coefficient acquisition apparatus.

FIG. 9 is a flowchart showing an example of a measurement processing flow for measuring a ground voltage of an electromagnetic noise.

FIG. 10 is an equivalent circuit diagram of the wearable measurement system when an operator grips a cable.

FIG. 11 is a graph showing a voltage measured by the voltage measurement apparatus when a capacitance between the upper electrode of the voltage measurement apparatus and the ground is changed.

FIG. 12 is a graph showing the relationship between the capacitance between the upper electrode of the voltage measurement apparatus and the ground and the height of a side wall of the lower electrode.

FIG. 13 is an equivalent circuit diagram of the wearable measurement system when the operator does not grip the cable.

FIG. 14 is a graph showing a voltage measured by the conversion coefficient acquisition apparatus when the capacitance between the upper electrode of the conversion coefficient acquisition apparatus and the ground is changed.

FIG. 15 is a graph showing the relationship between the capacitance between the upper electrode of the conversion coefficient acquisition apparatus and the ground and the height of the side wall of the lower electrode.

### DESCRIPTION OF EMBODIMENTS

An embodiment of the present invention will be described below with reference to the drawings. In the description provided with reference to the drawings, the same parts are denoted by the same reference numerals and the description thereof is omitted accordingly.

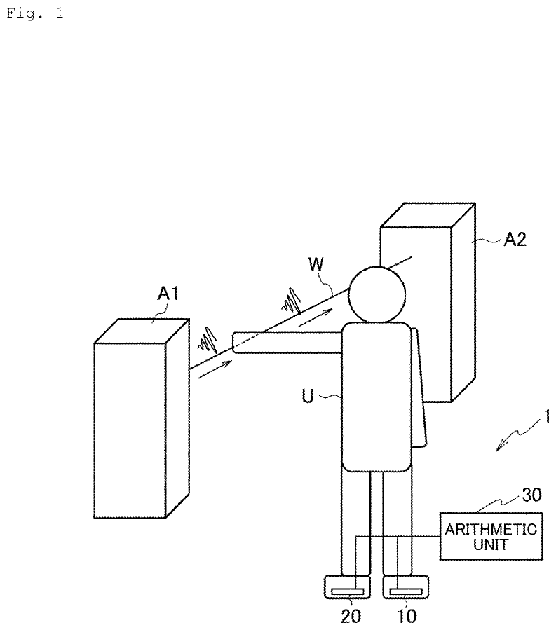

A wearable measurement system 1 of the present embodiment will be described with reference to FIG. 1. In FIG. 1, it is assumed that two apparatuses A1, A2 are connected by a cable W with coating, and electromagnetic noise is propagated from the apparatus A1 to the apparatus A2. The wearable measurement system 1 of FIG. 1 includes a voltage measurement apparatus 10, a conversion coefficient acquisition apparatus 20, and an arithmetic unit 30. The voltage measurement apparatus 10 is installed in one of shoes of an operator U, and the conversion coefficient acquisition apparatus 20 is installed on the other shoe. A computer such as a personal computer and a portable terminal can be used as the arithmetic unit 30.

As described in NPL 1, when the ground voltage is measured without grounding a measuring instrument, the level of the measured voltage changes according to the ground capacitance of the measuring instrument. When the same ground voltage is measured by the measuring instrument, the measured voltage becomes low when the ground capacitance is small, and becomes high when the ground capacitance is large. If a conversion coefficient X, which is the ratio of a measured voltage Vm to a ground voltage Vn of electromagnetic noise, can be obtained for each measurement environment, the ground voltage of the electromagnetic noise can be measured by a non-grounded measuring instrument. The conversion coefficient X is expressed by the following equation (1) using the measured voltage Vm and the ground voltage Vn of the electromagnetic noise.

$$X = Vn / Vm \qquad ( 1 )$$

In the wearable measurement system 1 of the present embodiment, first, the conversion coefficient acquisition apparatus 20 obtains the conversion coefficient X in a state where the operator U does not touch a cable W. Then, the voltage measurement apparatus 10 measures the voltage Vm generated in a voltage measurement circuit provided in itself in a state where the operator U touches the cable W. The arithmetic unit 30 receives the conversion coefficient X from the conversion coefficient acquisition apparatus 20, receives the measured voltage Vm from the voltage measurement apparatus 10, and multiplies the measured voltage Vm by the conversion coefficient X to obtain the ground voltage Vn of the electromagnetic noise.

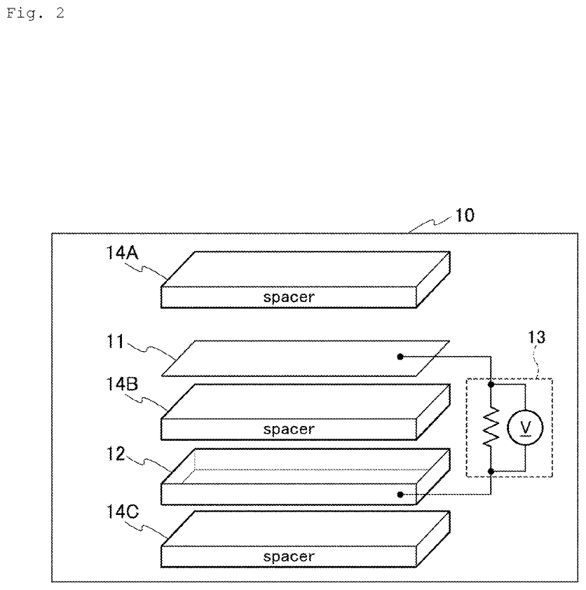

Next, an example of a configuration of the voltage measurement apparatus 10 will be described with reference to FIG. 2.

The voltage measurement apparatus 10 shown in FIG. 2 includes an upper electrode 11, a lower electrode 12, a voltage measurement circuit 13, and spacers 14A, 14B, 14C. The upper electrode 11, the lower electrode 12, and the spacers 14A, 14B, 14C are illustrated separately in FIG. 2, but in the order shown, the spacers 14C, The lower electrode 12, the spacer 14B, the upper electrode 11, and the spacer 14A are arranged so as to be overlapped with each other. Specifically, the spacer 14A is arranged on the upper surface of the upper electrode 11 so that the upper electrode 11 and the sole of the operator U do not come into contact with each other. The spacer 14B is arranged between the upper electrode 11 and the lower electrode 12 so that the upper electrode 11 and the lower electrode 12 do not come into contact with each other. The spacer 14C is arranged on the lower surface of the lower electrode 12 so that the lower electrode 12 and the ground do not come into contact with each other. For the upper electrode 11 and the lower electrode 12, for example, a conductor such as a copper plate can be used. For the spacers 14A, 14B, 14C, for example, an insulator such as acrylic can be used.

The lower electrode 12 has a water tank shape (a container with an opened upper surface) having a bottom surface 12A and a side wall 12B positioned on the outer periphery of the bottom surface 12A. The bottom surface 12A of the lower electrode 12 is arranged facing the ground.

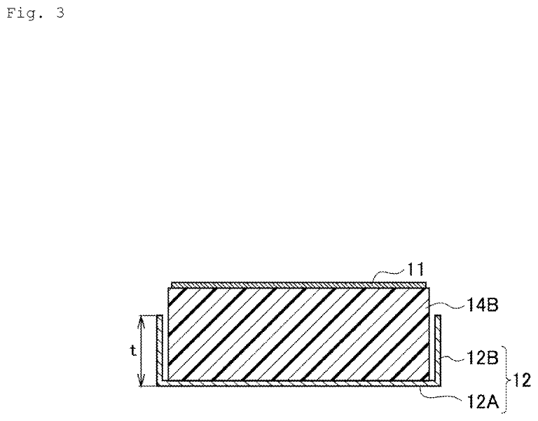

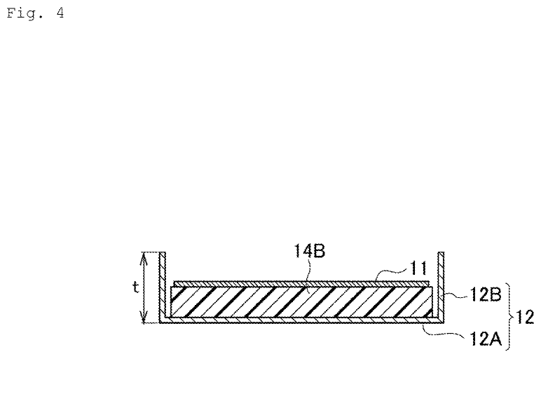

The upper electrode 11 is arranged so as to face the bottom surface 12A of the lower electrode 12. As shown in FIG. 3, the upper electrode 11 may be disposed at a position higher than a height t of the side wall 12B, or as shown in FIG. 4, the upper electrode 11 may be disposed at a position lower than the height t of the side wall 12B. When the upper electrode 11 is disposed at a position lower than the height t of the side wall 12B, the upper electrode 11 and the side wall 12B are not brought into contact with each other. For example, the size of the upper electrode 11 is set so as not to come into contact with the side wall 12B. The shape of the bottom surfaces 12A of the upper electrode 11 and the lower electrode 12 is not limited to a square shape, but may be circular or in any shape.

The voltage measurement circuit 13 is connected between the upper electrode 11 and the lower electrode 12, and measures the voltage Vm generated in the voltage measurement circuit 13. The ground voltage Vn of the electromagnetic noise can be obtained from the measured voltage Vm and the conversion coefficient X acquired by the conversion coefficient acquisition apparatus 20.

The upper electrode 11, the lower electrode 12, and the spacers 14A, 14B, 14C are arranged in a sole of the operator U. The voltage measurement circuit 13 may be disposed on the sole of the operator U or on another part constituting the shoe such as an upper.

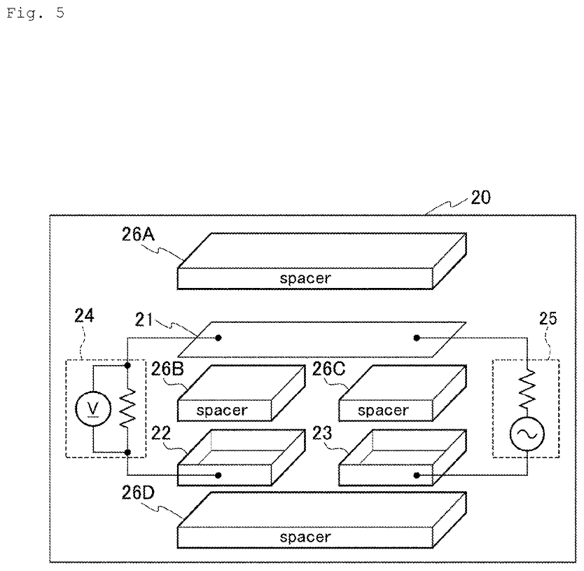

Next, an example of a configuration of the conversion coefficient acquisition apparatus 20 will be described with reference to FIG. 5.

The conversion coefficient acquisition apparatus 20 shown in FIG. 5 includes an upper electrode 21, two lower electrodes 22, 23, a voltage measurement circuit 24, an oscillation circuit 25, and spacers 26A, 26B, 26C, 26D. The upper electrode 21, the two lower electrodes 22, 23, and the spacers 26A, 26B, 26C, 26D are illustrated separately in FIG. 5, but in the order shown, the spacer 26D, the two lower electrodes 22, 23, the two spacers 26B, 26C, the upper electrode 21, and the spacer 26A are arranged in an overlapped manner. Specifically, the spacer 26A is arranged on the upper surface of the upper electrode 21 so that the upper electrode 21 and the sole of the operator U do not come into contact with each other. The spacers 26B, 26C are arranged between the upper electrode 21 and the lower electrodes 22, 23 so that the upper electrode 21 and the lower electrodes 22, 23 do not come into contact with each other. The spacer 26D is arranged on lower surfaces of the lower electrodes 22, 23 so that the lower electrodes 22, 23 and the ground do not come into contact with each other. For the upper electrode 21 and the lower electrodes 22, 23, for example, a conductor such as a copper plate can be used. For the spacers 26A, 26B, 26C, 26D, for example, an insulator such as acrylic can be used.

Each of the lower electrodes 22, 23 has a water tank shape having bottom surfaces 22A, 23A and side walls 22B, 23B positioned on the outer periphery of the bottom surfaces 22A, 23A, similarly to the lower electrode 12 of the voltage measurement apparatus 10. The bottom surfaces 22A, 23A of the lower electrodes 22, 23 are arranged at the same height so as to face the ground.

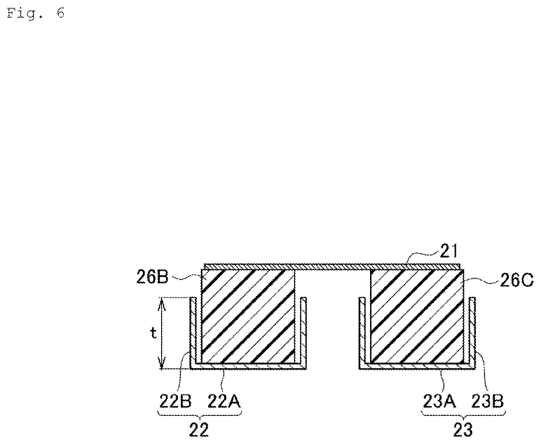

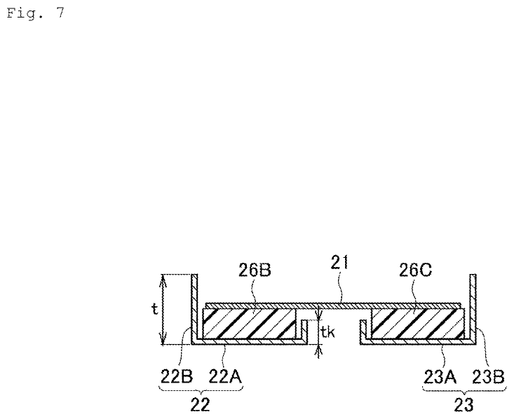

The upper electrode 21 is arranged so as to face each of bottom surfaces 22A, 23A of the lower electrodes 22, 23. As shown in FIG. 6, the upper electrode 21 may be disposed at a position higher than the height t of the side walls 22B, 23B, or as shown in FIG. 7, the upper electrode 21 may be disposed at a position lower than the height t of the side walls 22B, 23B. The shape of the bottom surfaces 22A, 23A of the upper electrode 21 and the lower electrodes 22, 23 is not limited to a square shape, but may be circular or in any shape.

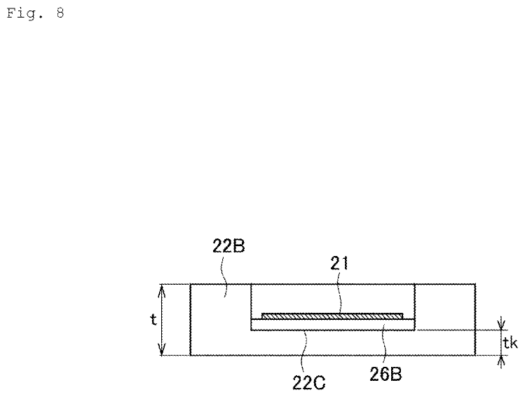

When the upper electrode 21 is disposed at a position lower than the height t of the side walls 22B, 23B, as shown in FIG. 8, a notch 22C is formed in the side wall 22B of the lower electrode 22 on the lower electrode 23 side so that the side wall 22B of the lower electrode 22 does not interfere with the upper electrode 21. Similarly, a notch is formed in the side wall 23B of the lower electrode 23 on the lower electrode 22 side. The upper electrode 21 is disposed at a position lower than the height t of the side walls 22B, 23B and higher than a height tk of the notched part.

The voltage measurement circuit 24 is connected to the upper electrode 21 and one of the lower electrodes 22, and measures a voltage Vr generated when the oscillation circuit 25 outputs a signal. The conversion coefficient X can be obtained from the measured voltage Vr.

The oscillation circuit 25 is connected to the upper electrode 21 and the other lower electrode 23, and outputs a signal of a predetermined frequency.

The upper electrode 21, the lower electrodes 22, 23, and the spacers 26A, 26B, 26C, 26D are arranged on a sole of the operator U. The voltage measurement circuit 24 and the oscillation circuit 25 may be disposed on the sole of the operator U, or may be disposed on another part constituting the shoe such as the upper.

The arithmetic unit 30 multiplies the measured voltage Vm measured by the voltage measurement apparatus 10 by the conversion coefficient X acquired by the conversion coefficient acquisition apparatus 20, to obtain the ground voltage Vn of the electromagnetic noise. Although the arithmetic unit 30 is shown as another unit in FIG. 1, the function of the arithmetic unit 30 may be mounted on the voltage measurement apparatus 10 or the conversion coefficient acquisition apparatus 20.

In FIGS. 2 and 5, all of the lower electrodes 12, 22, 23 of the voltage measurement apparatus 10 and the conversion coefficient acquisition apparatus 20 are of a water tank type, but at least one of the lower electrodes 12, 22, 23 may be of a water tank type having a bottom surface and a side wall around the bottom surface. For example, the lower electrode 12 may have a water tank shape, the lower electrodes 22, 23 may have a plate shape, or the lower electrode 12 may have a plate shape and the lower electrodes 22, 23 may have a water tank shape.

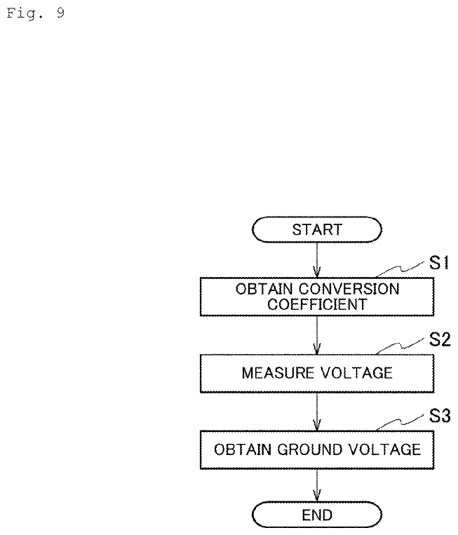

Next, a method of measuring the ground voltage of electromagnetic noise using the wearable measurement system 1 will be described with reference to the flowchart of FIG. 9.

Before going to the site where a communication failure occurs, the operator U performs preliminary calibration work. Specifically, in some environments where the ground voltage Vn of a signal simulating electromagnetic noise and the measured voltage Vm measured by the voltage measurement apparatus 10 are known, a signal is output from the oscillation circuit 25 to measure the voltage Vr generated in the voltage measurement circuit 24, and the correspondence between the voltage Vr and the conversion coefficient X is obtained. The correspondence may be stored in a storage unit held by the conversion coefficient acquisition apparatus 20, or the correspondence may be stored in the arithmetic unit 30. Note that NPL 1 describes an example of a calibration operation in which the correspondence between the voltage Vr and the conversion coefficient X is obtained on acrylic plates having different thicknesses.

The operator U wears the wearable measurement system 1 and stands at a place for measuring the ground voltage of the electromagnetic noise, and executes the following processing.

In step S1, the conversion coefficient acquisition apparatus 20 outputs a signal of a predetermined frequency from the oscillation circuit 25 in a state where the operator U does not touch the cable W, and measures the voltage Vr generated in the voltage measurement circuit 24. The conversion coefficient acquisition apparatus 20 obtains the conversion coefficient X from the measured voltage Vr on the basis of the correspondence obtained by the prior calibration work. Once the conversion coefficient X is obtained, the conversion coefficient acquisition apparatus 20 stops the output from the oscillation circuit 25. The operator U grabs the cable W.

In step S2, the voltage measurement apparatus 10 measures the voltage Vm generated in the voltage measurement circuit 13 in a state where the operator U touches the cable W.

In step S3, the arithmetic unit 30 multiplies the measured voltage Vm measured by the voltage measurement apparatus 10 by the conversion coefficient X obtained by the conversion coefficient acquisition apparatus 20, to obtain the ground voltage Vn of the electromagnetic noise.

By this processing described above, the ground voltage Vn of the electromagnetic noise can be measured.

Next, the influence of a capacitance Ca between the upper electrode 11 of the voltage measurement apparatus 10 and the ground will be described.

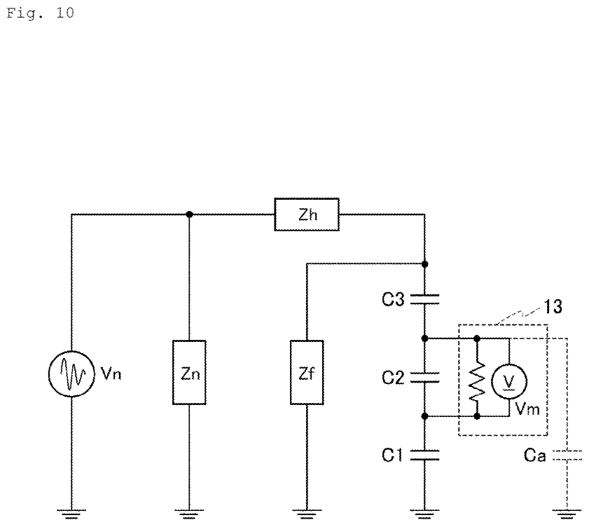

FIG. 10 shows an equivalent circuit of the wearable measurement system 1 when the operator U grabs the cable W. C1 is a capacitance between the lower electrode 12 and the ground. C2 is a capacitance between the upper electrode 11 and the lower electrode 12. C3 is a capacitance between the operator U and the upper electrode 11. Zn is an equivalent electromagnetic noise load impedance. Zh is impedance of the operator U including a capacitance between the cable W and the operator U. Zf is an impedance of the conversion coefficient acquisition apparatus 20 including a capacitance between the conversion coefficient acquisition apparatus 20 and the operator U and the ground. Vn is a ground voltage of electromagnetic noise to be measured. Vm is a voltage generated in the voltage measurement circuit 13.

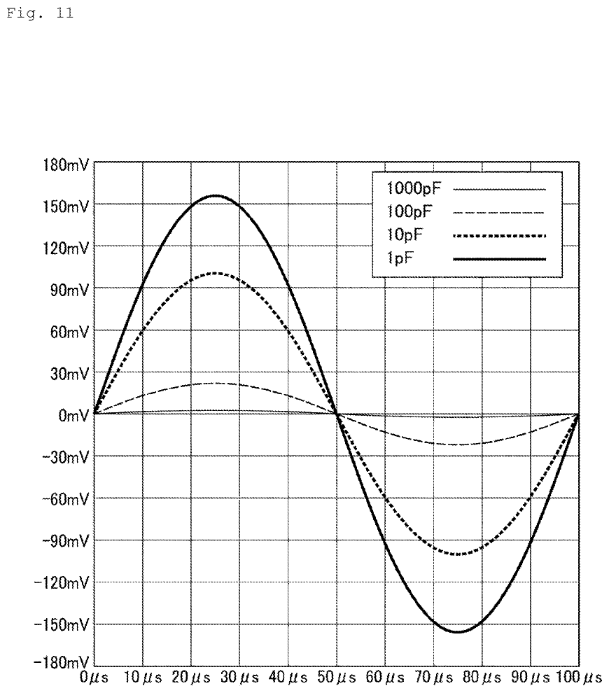

Note the voltage Vm that is generated in the voltage measurement circuit 13 when the operator U grabs the cable W. FIG. 11 shows a change in the voltage Vm generated in the voltage measurement circuit 13 when circuit analysis is performed while parameters in the equivalent circuit are fixed and the capacitance Ca is changed. FIG. 11 shows the measured voltage Vm when the capacitance Ca is changed to 1 pF, 10 pF, 100 pF, and 1000 pF. As shown in FIG. 11, the measured voltage Vm becomes smaller as the capacitance Ca becomes larger.

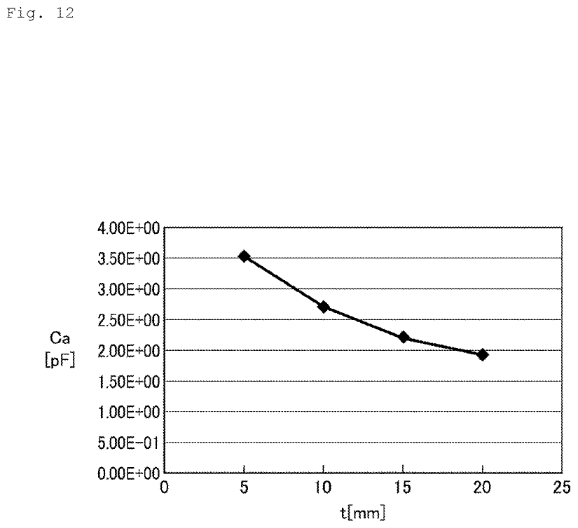

In the present embodiment, the lower electrode 12 is formed into a water tank type having the side wall 12B, wherein the capacitance Ca is reduced. FIG. 12 shows the results of obtaining the capacitance Ca by electromagnetic field analysis when the height t of the lower electrode 12 is changed. FIG. 12 shows the capacitance Ca obtained when the height t is changed to 5 mm, 10 mm, 15 mm, and 20 mm. The capacitance Ca can be reduced by forming the lower electrode 12 into a water tank type.

Next, the influence of a capacitance Cb between the upper electrode 21 of the conversion coefficient acquisition apparatus 20 and the ground will be described.

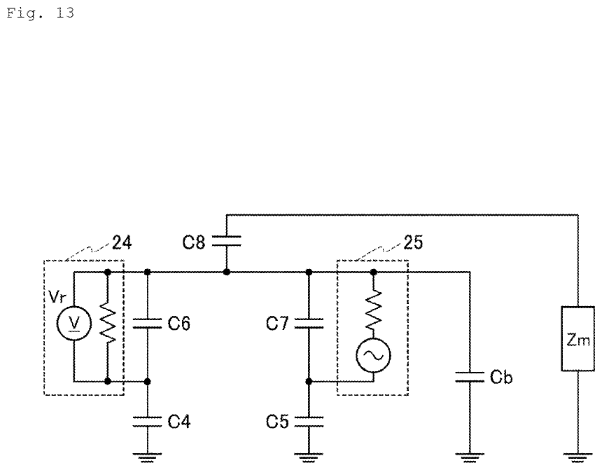

FIG. 13 shows an equivalent circuit of the wearable measurement system 1 when the operator U does not grab the cable W. C4 is a capacitance between the lower electrode 22 and the ground. C5 is a capacitance between the lower electrode 23 and the ground. C6 is a capacitance between the upper electrode 21 and the lower electrode 22. C7 is a capacitance between the upper electrode 21 and the lower electrode 23. C8 is a capacitance between the operator U and the upper electrode 21. Zm is an impedance of the voltage measurement apparatus 10 including a capacitance between the voltage measurement apparatus 10 and the ground. Vr is a voltage generated in the voltage measurement circuit 24 when the oscillation circuit 25 outputs a signal.

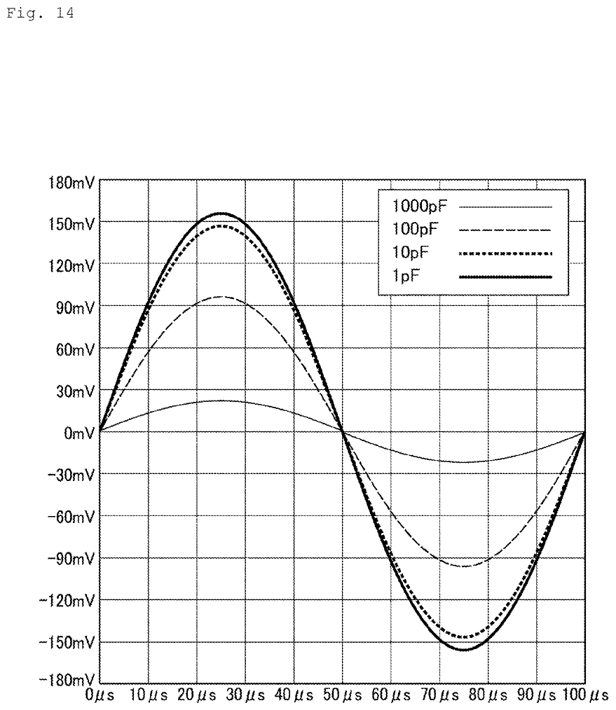

Note the voltage Vr that is generated in the voltage measurement circuit 24 when the oscillation circuit 25 outputs a signal. FIG. 14 shows a change in the voltage Vr generated in the voltage measurement circuit 24 when circuit analysis is performed while parameters in the equivalent circuit are fixed and the capacitance Cb is changed. FIG. 14 shows the measured voltage Vr when the capacitance Cb is changed to 1 pF, 10 pF, 100 pF, and 1000 pF. As shown in FIG. 14, the measured voltage Vr becomes smaller as the capacitance Cb becomes larger.

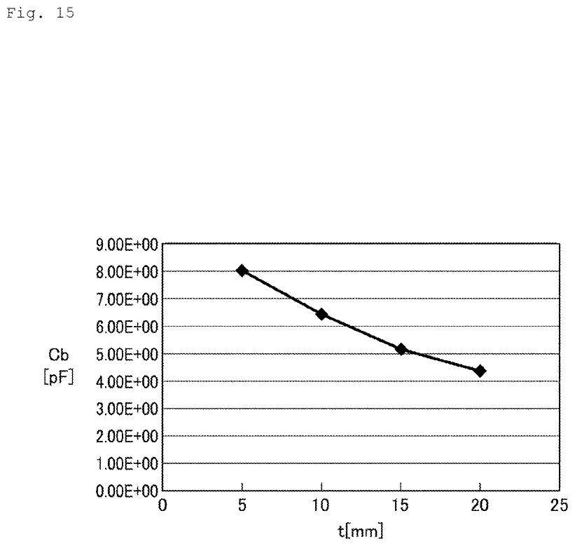

Similarly to the lower electrode 12 of the voltage measurement apparatus 10, the lower electrodes 22, 23 are formed into a water tank type having the side walls 22B, 23B, wherein the capacitance Cb is reduced. FIG. 15 shows the results of obtaining the capacitance Ca by electromagnetic field analysis when the height t of the lower electrodes 22, 23 is changed. FIG. 15 shows the capacitance Cb obtained when notches are formed in the lower electrodes 22, 23, the height tk of the notches is set to 0, and the height t is changed to 5 mm, 10 mm, 15 mm, and 20 mm. The capacitance Cb can be reduced by forming the lower electrodes 22, 23 into a water tank type.

As described above, the wearable measurement system 1 according to the present embodiment includes the voltage measurement apparatus 10 and the conversion coefficient acquisition apparatus 20. The voltage measurement apparatus 10 includes the lower electrode 12, the upper electrode 11 arranged opposite to the lower electrode 12, and the voltage measurement circuit 13 connected between the lower electrode 12 and the upper electrode 11. The conversion coefficient acquisition apparatus 20 includes the lower electrode 22, the lower electrode 23 arranged side by side at the same height as the lower electrode 22, the upper electrode 21 arranged opposite to the lower electrodes 22, 23, the voltage measurement circuit 24 connected between the lower electrode 22 and the upper electrode 21, and the oscillation circuit 25 connected to the lower electrode 23 and the upper electrode 21 and outputting a signal of a predetermined frequency. The lower electrodes 12, 22, 23 of the voltage measurement apparatus 10 and the conversion coefficient acquisition apparatus 20 have a container shape having a bottom surface and side walls around the bottom surface. Thus, capacitances Ca, Cb that are generated between the upper electrodes 11, 21 of the voltage measurement apparatus 10 and the conversion coefficient acquisition apparatus 20 and the ground can be reduced. As a result, not only is it possible to measure the ground voltage of small electromagnetic noise, but also the ground voltage can be measured at a place where the distance between the measurement environment and the ground is separated.

### REFERENCE SIGNS LIST

1 Wearable measurement system
10 Voltage measurement apparatus
11 Upper electrode
12 Lower electrode
12A Bottom surface
12B Side wall
13 Voltage measurement circuit
14A, 14B, 14C Spacer
20 Conversion coefficient acquisition apparatus
21 Upper electrode
22.23 Lower electrode
22A, 23A Bottom surface
22B, 23B Side wall
24 Voltage measurement circuit
25 Oscillation circuit
26A, 26B, 26C, 26D Spacer
30 Arithmetic unit

1. A measurement system for measuring a ground voltage of electromagnetic noise generated in a cable, comprising:
a conversion coefficient acquisition apparatus and a voltage measurement apparatus,
wherein the conversion coefficient acquisition apparatus includes:
a first lower electrode,
a second lower electrode arranged side by side at a same height as the first lower electrode,
a first upper electrode arranged opposite to the first lower electrode and the second lower electrode,
a first voltage measurement circuit connected between the first lower electrode and the first upper electrode, and
an oscillation circuit that is connected to the second lower electrode and the first upper electrode and that is configured to output a signal of a predetermined frequency,
wherein the first voltage measurement circuit is configured to, based on the oscillation circuit outputting a signal while an operator stands on the first upper electrode and is not in contact with the cable, measure a first voltage generated in the first voltage measurement circuit and obtain a conversion coefficient based on the first voltage, and
wherein the voltage measurement apparatus includes:
a third lower electrode,
a second upper electrode arranged opposite to the third lower electrode, and
a second voltage measurement circuit connected between the third lower electrode and the second upper electrode,
wherein the second voltage measurement circuit is configured to measure a second voltage generated in the second voltage measurement circuit while the operator stands on the second upper electrode and is in contact with the cable, and obtain a ground voltage of the electromagnetic noise generated in the cable by multiplying the second voltage by the conversion coefficient, and
wherein at least one of the first lower electrode, the second lower electrode, or the third lower electrode has a container shape with a bottom surface and side walls around the bottom surface.

2. The measurement system according to claim 1,
wherein the first upper electrode is disposed at a position lower than a height of side walls of the first lower electrode and the second lower electrode, and
wherein the side wall of the first lower electrode on a second lower electrode side and the side wall of the second lower electrode on a first lower electrode side are formed with notches so as not to interfere with the first upper electrode.

3. The measurement system according to claim 1, wherein the second upper electrode is disposed at a position lower than a height of a side wall of the third lower electrode.

4. A conversion coefficient acquisition apparatus, comprising:
a first lower electrode;
a second lower electrode arranged side by side at a same height as the first lower electrode;
a first upper electrode arranged opposite to the first lower electrode and the second lower electrode;
a first voltage measurement circuit connected between the first lower electrode and the first upper electrode; and
an oscillation circuit that is connected to the second lower electrode and the first upper electrode and that is configured to output a signal of a predetermined frequency,
wherein the first voltage measurement circuit is configured to, based on the oscillation circuit outputting a signal while an operator stands on the first upper electrode and is not in contact with a cable, measure a first voltage generated in the first voltage measurement circuit and obtain a conversion coefficient based on the first voltage, and
wherein the first lower electrode and the second lower electrode have a container shape including a bottom surface and side walls around the bottom surface.

5. A voltage measurement apparatus, comprising:
a first lower electrode;
a second upper electrode arranged opposite to the first lower electrode; and
a second voltage measurement circuit connected between the first lower electrode and the second upper electrode,
wherein the second voltage measurement circuit is configured to measure a second voltage generated in the second voltage measurement circuit while an operator stands on the second upper electrode and is in contact with a cable, and obtain a ground voltage of electromagnetic noise generated in the cable by multiplying the second voltage by a conversion coefficient, and
wherein the first lower electrode has a container shape including a bottom surface and side walls around the bottom surface.
